(19) United States
(12) Patent Application Publication
(10) Pub. No.: US 2024/0023420 A1
(43) Pub. Date: Jan. 18, 2024

(54) DISPLAY PANEL AND MANUFACTURING METHOD THEREOF

(71) Applicants: WUHAN CHINA STAR OPTOELECTRONICS TECHNOLOGY CO., LTD., Wuhan (CN); WUHAN CHINA STAR OPTOELECTRONICS SEMICONDUCTOR DISPLAY TECHNOLOGY CO., LTD., Wuhan (CN)

(72) Inventor: Deqi WANG, Wuhan (CN)

(73) Assignees: WUHAN CHINA STAR OPTOELECTRONICS TECHNOLOGY CO., LTD., Wuhan (CN); WUHAN CHINA STAR OPTOELECTRONICS SEMICONDUCTOR DISPLAY TECHNOLOGY CO., LTD., Wuhan (CN)

(21) Appl. No.: 17/311,368

(22) PCT Filed: May 18, 2021
(86) PCT No.: PCT/CN2021/094393

§ 371 Date: Nov. 17, 2022

(30) Foreign Application Priority Data
May 10, 2021 (CN) 202110504090.8

(51) Int. Cl. H10K 59/95; H10K 59/80; H10K 71/50

(52) U.S. Cl. CPC H10K 59/95; H10K 59/872; H10K 71/50; H10K 2102/311

(57) ABSTRACT

The present application discloses a display panel and a manufacturing method thereof. In the present application, two display panels are formed on front and back surfaces of a substrate, and a double-surfaced display panel is formed combined with a pad bending process, thereby increasing a display area, maximizing use of space on the substrate, and preventing a problem of interference between control areas of the double panels.

### BACKGROUND OF INVENTION

### Field of Invention

The present disclosure relates to the field of display technology, in particular to a display panel and a manufacturing method thereof.

### Description of Prior Art

Organic electroluminescent display (OLED) panels have gradually become a mainstream technology in the display field due to their unique advantages such as low power consumption, high saturation, fast response times, and wide viewing angles. In the future, the OLEDs will have broad application space in vehicles, mobile phones, tablets, computers, and TV products.

The OLEDs usually adopt a sandwich structure. When current is applied to both ends, electrons and holes are injected into an organic light-emitting layer, and different organic light-emitting materials emit light of different colors under excitation of excitons. Therefore, the OLEDs are used in various display products.

### SUMMARY OF INVENTION

The present disclosure aims to provide a display panel and a manufacturing method thereof, in order to prevent interference between control areas of two panels.

To achieve the above propose, the present disclosure provides a display panel, wherein the display panel comprises:
a substrate;
a first display unit and a first fixing unit disposed on a first surface of the substrate; and
a second display unit disposed on a second surface of the substrate away from the first display unit,
wherein the second display unit is fixed to the first fixing unit through a first connecting unit.

In a preferable embodiment, the second display unit is located on the second surface at a same side as the first fixing unit.

The present disclosure further provides a manufacturing method of a display panel, the manufacturing method comprises:
providing a substrate;
forming a first display unit and a first fixing unit on a first surface of the substrate;
forming a second display unit and a second fixing unit on a second surface of the substrate away from the first display unit;
fixing the first display unit to the second fixing unit through a second connecting unit; and
fixing the second display unit to the first fixing unit through a first connecting unit.

Beneficial effect of the present disclosure: in the technical solution of the present disclosure, two display panels are formed on front and back surfaces of a substrate, and a double-surfaced display panel is formed combined with a pad bending process, thereby increasing a display area, maximizing use of space on the substrate, and preventing a problem of interference between control areas of the double panels.

### DESCRIPTION OF DRAWINGS

Technical solutions and other beneficial effects of the present disclosure will be obvious by describing specific embodiments of the present disclosure in detail below in conjunction with accompanying drawings.

FIG. 1 shows a schematic diagram of an example of a display panel of the present disclosure.

FIG. 2 shows a schematic diagram of another example of a display panel of the present disclosure.

FIG. 3 shows a schematic diagram of yet another example of a display panel of the present disclosure.

FIG. 4 shows a flow chart of a manufacturing method of the display panel of the present disclosure.

FIG. 5 shows a schematic diagram of forming a first display unit and a first fixing unit on a substrate during a manufacturing process of the display panel of the present disclosure.

FIG. 6 shows a schematic diagram of forming a second display unit and a second fixing unit on the substrate during the manufacturing process of the display panel of the present disclosure.

FIG. 7 shows a schematic diagram of forming a second connecting unit during the manufacturing process of the display panel of the present disclosure.

FIG. 8 shows a schematic diagram of forming a first connecting unit during the manufacturing process of the display panel of the present disclosure.

FIG. 9 is a schematic diagram of a manufacturing process of an OLED display panel of the present disclosure.

### REFERENCE SIGNS

1. Substrate.
2. First display unit.
3. First fixing unit.
4. Second display unit.
5. Second fixing unit.
6. First connecting unit.
7. Second connecting unit.
8. OLED display panel; 801, buffer layer; 802, back plate layer; 803, electroluminescent layer; 804, thin-film encapsulation layer; 805, touch layer; 806, polarizing layer; 807, optical adhesive layer; 808, color cover plate.

### DETAILED DESCRIPTION OF EMBODIMENTS

Technical solutions in embodiments of the present disclosure will be clearly and completely described below in conjunction with drawings in the embodiments of the present disclosure. Obviously, the described embodiments are only a part of embodiments of the present disclosure, rather than all the embodiments. It should be noted that the embodiments in the present disclosure and the features in the embodiments can be combined with each other if there is no conflict.

In the description of the present disclosure, it should be understood that orientations or position relationships indicated by the terms “center”, “longitudinal”, “lateral”, “length”, “width”, “thickness”, “upper”, “lower”, “front”, “rear”, “left”, “right”, “vertical”, “horizontal”, “top”, “bottom”, “inside”, “outside”, “clockwise”, and “counter-clockwise” are based on orientations or position relationships illustrated in the drawings. The terms are used to facilitate and simplify the description of the present disclosure, rather than indicate or imply that the devices or elements referred to herein are required to have specific orientations or be constructed or operate in the specific orientations. Accordingly, the terms should not be construed as limiting the present disclosure. In addition, the term “first”, “second” are for illustrative purposes only and are not to be construed as indicating or imposing a relative importance or implicitly indicating the number of technical features indicated. Thus, a feature that limited by “first”, “second” may expressly or implicitly include at least one of the features. In the description of the present disclosure, the meaning of “plural” is two or more, unless otherwise specifically defined.

In the description of the present disclosure, it should be noted that the terms “installation”, “connection” and “coupling” should be understood in a broad sense, unless otherwise clearly specified and defined. For example, it can be a fixed connection, a detachable connection, or integrated connection; it can be a mechanical connection, an electrical connection or can communicate with each other; it can be directly connected or indirectly connected through an intermediary, it can also be the connection between two elements or the interaction between two elements. Those ordinary skilled in the art can understand the specific meanings of the above terms in the present disclosure according to specific situations.

In the present disclosure, it should be noted that unless otherwise clearly defined and limited, a first feature “on” or “under” a second feature may mean that the first feature directly contacts the second feature, or that the first feature contacts the second feature via an additional feature there between instead of directly contacting the second feature. Moreover, the first feature “on”, “above”, and “over” the second feature may mean that the first feature is right over or obliquely upward over the second feature or mean that the first feature has a horizontal height higher than that of the second feature. The first feature “under”, “below”, and “beneath” the second feature may mean that the first feature is right beneath or obliquely downward beneath the second feature or mean that that horizontal height of the first feature is lower than that of the second feature.

The following description provides various embodiments or examples for implementing various structures of the present disclosure. To simplify the description of the present disclosure, parts and settings of specific examples are described as follows. Certainly, they are only illustrative, and are not intended to limit the present disclosure. Further, reference numerals and reference letters may be repeated in different examples. This repetition is for purposes of simplicity and clarity and does not indicate a relationship of the various embodiments and/or the settings. Furthermore, the present disclosure provides specific examples of various processes and materials, however, applications of other processes and/or other materials may be appreciated those skilled in the art.

After analysis and research on existing technology, currently, control areas between double-surfaced display panels are not set reasonably enough, and there will be interference between the control areas, which affects function of the display panels. In order to solve the interference problem, a size of a substrate 1 needs to increase. However, this will be accompanied by other problems, such as increasing areas of the display panels, increasing production costs, and increasing processing procedures.

Therefore, the present disclosure aims to provide a display panel in which OLED display panels 8 are respectively disposed on front and back surfaces of a same substrate 1. A first OLED display panel is connected to a fixing element disposed on the back surface of the substrate 1 by using a pad bending process, and a second OLED display panel is connected to a fixing element disposed on the front surface of the substrate 1, so as to prevent interference between control areas of the two OLED display panels 8 and maximize use of space on the substrate 1 without increasing or increasing less of an area of the substrate 1.

The present disclosure discloses a display panel comprising: the substrate 1, a first display unit 2, a second display unit 4, a first fixing unit 3, and a first connecting unit 6. The first display unit 2 and the first fixing unit 3 are disposed on a first surface of the substrate 1. The second display unit 4 is disposed on a second surface of the substrate 1 away from the first display unit 2 and is disposed at a same side as the first fixing unit 3. The second display unit 4 and the first fixing unit 3 are connected and fixed by the first connecting unit 6.

In the present disclosure, the substrate 1 can be used as a base, the first display unit 2 is formed at a side of the front surface of the substrate 1, and the first fixing unit 3 is formed at another side of the front surface of the substrate 1. The second display unit 4 is formed on the back surface of the substrate 1 and is located at a same side as a second fixing unit 5.

In an example, the first OLED display panel is formed on a front surface of a stainless steel base, and a first fixing element is formed between the first OLED display panel and an edge of the base. In order to facilitate connection, the first fixing element may be disposed close to the edge of the stainless steel base. The second OLED display panel is formed on a back surface of the stainless steel base, and the second OLED display panel is connected to the first fixing element by a connecting terminal, so that the first fixing element is used as a control area of the second OLED display panel, and the control area comprises a pad bending area and a fingerprint unlock area.

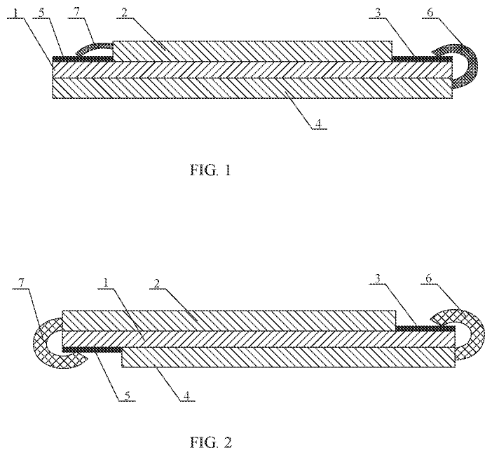

In the present disclosure, as shown in FIG. 1, a second fixing unit 5 may be additionally disposed on the first surface of the substrate 1, and the first display unit 2 and the second fixing unit 5 are connected and fixed by a second connecting unit 7. However, control areas of the two display units are formed on a same surface of the substrate 1, which will affect and occupy a display area of the first display unit 2. If the two fixing units are disposed at a same side, a problem of mutual influence of the control areas is likely to occur.

Therefore, as shown in FIG. 2, in the present disclosure, the second fixing unit 5 can be further disposed on the second surface of the substrate 1, and the second fixing unit 5 and the first fixing unit 3 are respectively located at both sides of the substrate 1. The second display unit 4 is located on the second surface at a same side as the second fixing unit 5, and the second fixing unit 5 is located on the second surface of the substrate 1 at a same side as the first display unit 2.

In an example, the first OLED display panel is formed at a side of the front surface of the stainless steel base, and the first fixing element is formed at another side of the front surface of the stainless steel base. On the back surface of the stainless steel base, the second OLED display panel is formed at a same side as the first fixing element, and on the back surface of the stainless steel base, a second fixing element is formed at a same side as the first OLED display panel. The second OLED display panel is connected to the first fixing element by using a first connecting terminal, and the first OLED display panel is connected to the second fixing element by using a second connecting terminal. In this way, the control areas of the two panels are completely staggered so as to prevent mutual influence. In addition, the fixing elements are respectively arranged on the front and back surfaces of the base, which can reduce influence on a display area of the display panel disposed on a surface.

In the present disclosure, the connecting terminal may be a bent pad structure formed by the pad bending process. A bottom of a flexible display panel is disposed with dense wire areas and binding areas, which are called terminal areas or external wire areas. A process of bending the terminal areas to another side of the flexible display panel is called the pad bending process, which aims to narrow a bottom border. The structure can also be used for integrated installation of mobile phone batteries, chips, and other devices.

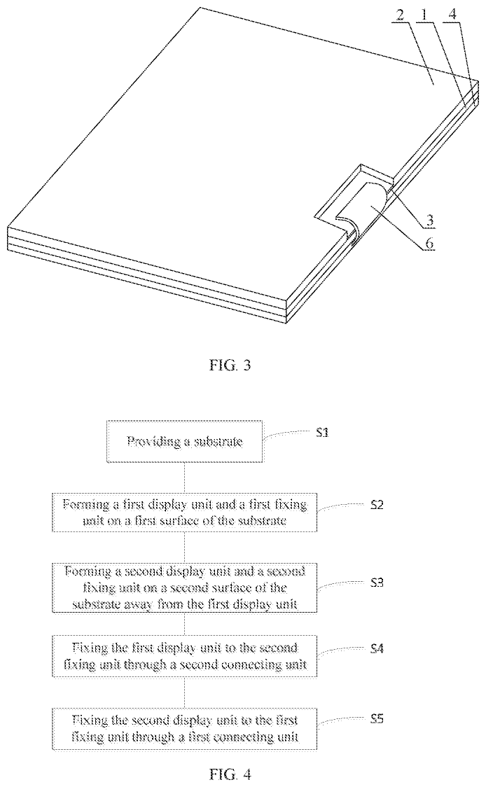

In the present disclosure, in order to install the fixing element, as shown in FIG. 1 or FIG. 2, the substrate 1 can be expanded a certain distance, i.e., a size of the substrate 1 is greater than a size of the display panel, so that the fixing element can be disposed at a position between the display unit and the substrate 1. As shown in FIG. 3, the substrate 1 and the display panel can also be designed to have a same size. However, a groove area needs to be reserved on the display unit, and the fixing element is located in the groove area and is disposed close to an edge of the substrate 1. FIG. 3 is a schematic diagram of a groove area reserved on the first display unit 2. A reservation method of the second display unit 4 is basically the same as a groove area reservation method of the first display unit 2, and will not be repeated here. In FIG. 3, since the second display unit 4 is located on another surface of the substrate, the second display unit and the groove area reserved thereon are not shown in the figure.

It should be noted here that the positions of the fixing elements above are only examples. On the premise that the pad bending process can be completed, the positions of the fixing elements and the OLED display panels on the substrate can be adjusted appropriately to meet requirements of process.

In addition, in order to meet requirement of narrow frame as much as possible in the present disclosure, an expansion distance of the substrate 1 should not be too large. Compared with a width of the OLED display panel, the expansion distance can be expanded by 2 mm to 4 mm. A size of the fixing element cannot be greater than an expansion range of the substrate 1, and a preferred width is 1 mm to 2 mm.

In the present disclosure, both of the two display units can adopt the OLED display panel 8, which is formed on the substrate 1 in a stacked structure. The OLED display panel 8 comprises a cover window (CW), an optically clear adhesive (OCA), a polarizer (POL), a touch panel (TP), an electroluminescence (EL), a thin-film encapsulation (TFE), a back plate (BP), and a foam film layer.

In the present disclosure, the two display panels are formed on the front and back surfaces of the same base. The pad bending process is used to make the two display panels form the connecting terminals with the curved pad structure at both sides of the substrate 1, thereby adding the display areas of the double-surfaced display panels, and maximize the use of the space on the substrate 1. At the same time, it is possible to prevent the problem of mutual influence between the control areas of the double panels.

Correspondingly, the present disclosure also provides an exemplary manufacturing process for manufacturing display panels in some embodiments. It should be understood that the following operations are not exhaustive and other operations can also be performed before, after, or between any illustrated operations. In addition, some operations can be performed at the same time or in a different order.

As shown in FIG. 4, the manufacturing method comprises:

S1, providing the substrate 1;

S2, forming the first display unit 2 and the first fixing unit 3 on the first surface of the substrate 1;

S3, forming the second display unit 4 and the second fixing unit 5 on the second surface of the substrate 1 away from the first display unit 2;

S4, fixing the first display unit 2 to the second fixing unit 5 through the second connecting unit 7;

S5, fixing the second display unit 4 to the first fixing unit 3 through the first connecting unit 6.

In the present disclosure, the substrate 1 provided in the step S1 may be a rigid substrate 1, for example, a glass substrate 1, a stainless steel substrate 1, and the like. It is also possible to adopt a bendable flexible substrate 1, for example, a substrate 1 formed by various plastic films, such as polyethylene terephthalate (PET), polyethersulfone, polycarbonate or polyimide and derivatives thereof, etc.

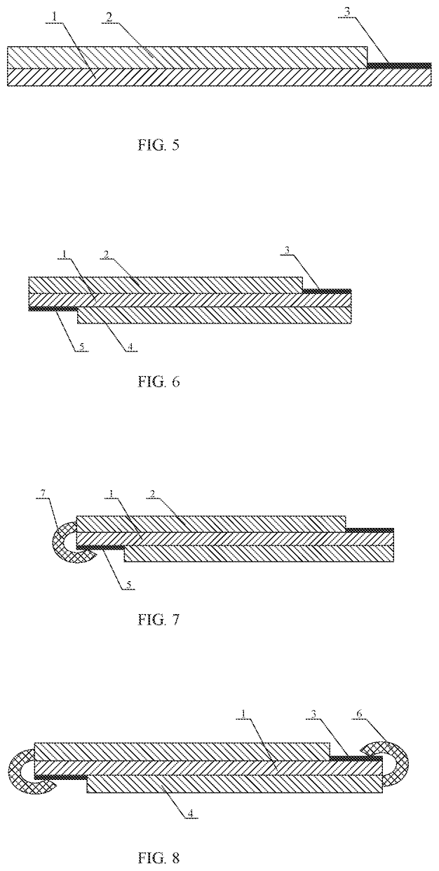

In the step S2 of the present disclosure, the first display unit 2 is formed at a side of the first surface of the substrate, and the first fixing unit 3 is formed at another side of the first surface. As shown in FIG. 5, in an example, a stainless steel material is used as the base, and the first display unit 2 is formed at a left side of the first surface of the base through a display panel manufacturing process and is flush with the left edge of the base, and remaining space on the first surface of the base can be used to form the first fixing element as the first fixing unit 3. Under the condition that the display effect is not affected and the base space is utilized to the maximum, the size of the first fixing element is minimized to make the size of the display panel on the first surface as large as possible to increase the display area and reduce the size of the base. The first fixing element may be adjacent to or not in contact with the first display panel. In order to facilitate the implementation of the pad bending process, the first fixing element is disposed as close as possible to the edge of the base.

In the step S3 of the present disclosure, the second display unit 4 and the second fixing unit 5 are formed at a side of the second surface of the substrate 1. Wherein, the second surface of the substrate 1 is a surface away from the first display unit 2. As shown in FIG. 6, in an example, the second display unit 4 is formed at a right side of the second surface of the stainless steel base by the display panel manufacturing process and is flush with the right edge of the base, i.e., the second display unit 4 is disposed at a same side with the first fixing unit 3. Remaining space on the second surface of the base can be used to form the second fixing element as the second fixing unit 5. Design idea of the second fixing element is basically the same as that of the first fixing element. The size of the second fixing element is reduced as much as possible to make the size of the second display unit 4 as large as possible to increase the display area and reduce the size of the base. The second fixing element may be adjacent to or not in contact with the second display panel. In order to facilitate implementation of the pad bending process, the second fixing element is disposed as close as possible to the edge of the base.

In the step S4 of the present disclosure, as shown in FIG. 7, a side of the second connecting unit 7 is bound to the first display unit 2 by the pad bending process, and another side of the second connecting unit 7 is fixed to the second fixing unit 5. A side (or an end) of the connecting terminal is bound to a binding area of the first display panel, and another side (or another end) of the connecting terminal is connected to the second fixing element Stiffener-2. The second fixing element can be used to install devices such as a fingerprint unlocking board and a driving chip for controlling the first display panel, and auxiliary components such as a battery can also be arranged at this position.

In the step S5 of the present disclosure, as shown in FIG. 8, a side of the first connecting unit 6 is bound to the second display unit 4 by the pad bending process, and another side of the first connecting unit 6 is fixed to the first fixing unit 3. A side (or an end) of the connecting terminal is bound to a binding area of the second display panel, and another side (or another end) of the connecting terminal is connected to the first fixing element Stiffener-1. The first fixing element can be used to install devices such as the fingerprint unlocking board and the driving chip for controlling the second display panel, and the auxiliary components such as the battery can also be arranged at this position.

In the present disclosure, the fixing element stiffener can be an organic polymer material such as polyimide (PI) and polyethylene terephthalate (PET).

In the present disclosure, both the first display unit 2 and the second display unit 4 adopt the OLED display panel 8, and both are formed on the substrate 1 by adopting an OLED display panel manufacturing process.

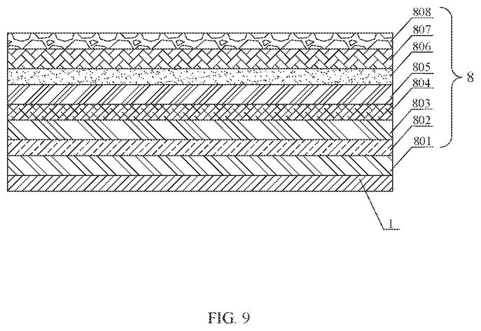

As shown in FIG. 9, the manufacturing process of the OLED display panel 8 is as follows: firstly, a buffer layer 801 is formed on the substrate 1 using foam materials; a back plate layer 802 is fixed on the buffer layer 801 by an adhesive; and an electroluminescent layer and a thin-film encapsulation layer 804 are sequentially formed on the back plate layer 802. Further, a touch layer 805, a polarizing layer 806, an optical adhesive layer 807, and a color cover plate 808 are sequentially formed on the thin-film encapsulation layer 804, thereby completing the preparation of the OLED display panel 8.

Obviously, the above mentioned embodiments of the present disclosure are merely examples to clearly illustrate the present disclosure, and are not meant to limit the implementation of the present disclosure. For those of ordinary skill in the art, there are other different forms of changes on the basis of the above description, and it is not possible to list all the implementations here. Any obvious changes derived from the technical solutions of the present disclosure are still within the scope of protection of the present disclosure.

1. A display panel, wherein the display panel comprises:
a substrate (1);
a first display unit (2) and a first fixing unit (3) disposed on a first surface of the substrate (1); and
a second display unit (4) disposed on a second surface of the substrate (1) away from the first display unit (2),
wherein the second display unit (4) is fixed to the first fixing unit (3) through a first connecting unit (6).

2. The display panel of claim 1, wherein the second display unit (4) is located on the second surface at a same side as the first fixing unit (3).

3. The display panel of claim 1, wherein the display panel further comprises: a second fixing unit (5) located on a same surface of the substrate (1) as the second display unit (4);
wherein the first display unit (2) is fixed to the second fixing unit (5) through a second connecting unit (7).

4. The display panel of claim 3, wherein the first fixing unit (3) and the second fixing unit (5) are respectively located at both sides of the substrate (1).

5. The display panel of claim 3, wherein the first fixing unit (3) the second fixing unit (5) comprise: a fixing element fixed on the substrate (1).

6. The display panel of claim 3, wherein the first fixing unit (3) comprises: a fixing element fixed on the substrate (1).

7. The display panel of claim 3, wherein the second fixing unit (5) comprises: a fixing element fixed on the substrate (1).

8. The display panel of claim 3, wherein the first connecting unit (6) and the second connecting unit (7) comprise: a connecting terminal for connecting and fixing a display unit and a fixing unit.

9. The display panel of claim 3, wherein the first connecting unit comprises: a connecting terminal for connecting and fixing a display unit and a fixing unit.

10. The display panel of claim 3, wherein the second connecting unit (7) comprises: a connecting terminal for connecting and fixing a display unit and a fixing unit.

11. The display panel of claim 3, wherein the first display unit (2) and the second display unit (4) comprise: an OLED display panel (8).

12. The display panel of claim 3, wherein the first display unit (2) comprises: an OLED display panel (8).

13. The display panel of claim 3, wherein the second display unit (4) comprises: an OLED display panel (8).

14. A manufacturing method of a display panel, wherein
the manufacturing method comprises:
providing a substrate (1);
forming a first display unit (2) and a first fixing unit (3) on a first surface of the substrate (1);
forming a second display unit (4) and a second fixing unit (5) on a second surface of the substrate (1) away from the first display unit (2);
fixing the second display unit (4) to the first fixing unit (3) through a first connecting unit (6); and
fixing the first display unit (2) to the second fixing unit (5) through a second connecting unit (7).

15. The manufacturing method of the display panel of claim 14, wherein the step of forming the second display unit (4) and the second fixing unit (5) on the second surface of the substrate (1) away from the first display unit (2) comprises:
forming the second display unit (4) at a same side of the first fixing unit (3) on the second surface of the substrate (1) away from the first display unit (2); and
forming the second fixing unit (5) at a same side of the first display unit (2) on the second surface of the substrate (1) away from the first display unit (2).

16. (canceled)

17. The manufacturing method of the display panel of claim 14, wherein the step of forming the first display unit (2) comprises:
forming a buffer layer on the surface of the substrate (1);
forming a back plate layer at a side of the buffer layer away from the substrate (1);
forming an electroluminescent layer at a side of the back plate layer away from the buffer layer;
forming a thin-film encapsulation layer at a side of the electroluminescent layer away from the first back plate layer;
forming a touch layer at a side of the thin-film encapsulation layer away from the electroluminescent layer;
forming a polarizing layer at a side of the touch layer away from the first electroluminescent layer;
forming an optical adhesive layer at a side of the polarizing layer away from the touch layer; and
forming a cover plate at a side of the optical adhesive layer away from the polarizing layer.

18. The manufacturing method of the display panel of claim 14, wherein the step of forming the second display unit (4) comprises:
forming a buffer layer on the second surface of the substrate (1) away from the second display unit (4);
forming a back plate layer at a side of the buffer layer away from the substrate (1);
forming an electroluminescent layer at a side of the back plate layer away from the buffer layer;
forming a thin-film encapsulation layer at a side of the electroluminescent layer away from the back plate layer;
forming the touch layer at a side of the thin-film encapsulation layer away from the electroluminescent layer;
forming a polarizing layer at a side of the touch layer away from the electroluminescent layer;
forming an optical adhesive layer at a side of the polarizing layer away from the touch layer; and
forming a cover plate at a side of the optical adhesive layer away from the polarizing layer.
